(19) United States
(12) Patent Application Publication
(10) Pub. No.: US 2007/0279078 A1
(43) Pub. Date: Dec. 6, 2007

(54) Kelvin contact measurement device and kelvin contact measurement method

(75) Inventor: Tsutomu Iwami, Kanagawa (JP)

Correspondence Address: YOUNG & THOMPSON, 745 SOUTH 23RD STREET, 2ND FLOOR, ARLINGTON, VA, 22202, US

(73) Assignee: NEC ELECTRONICS CORPORATION, KANAGAWA (JP)

(21) Appl. No.: 11/785,297

(22) Filed: Apr. 17, 2007

(30) Foreign Application Priority Data
Apr. 19, 2006 (JP) 2006-115691

(51) Int. Cl. G01R 1/073; G01R 31/02

(52) U.S. Cl. 324/761

(57) ABSTRACT

Stable Kelvin contact is made upon positional deviation of object. Force pins 12a and sense pins 12b contact with each ball terminal 51 of object 50 for measuring electric property. Force pins 12a and sense pins 12b are extendable and contractable and urged to ball terminal 51 by elastic member 13. Four force and sense pins correspond to one ball terminal. At least one force pin 12a and at least one sense pin 12b are arranged to come into contact with the one ball terminal 51. The object is positioned in concave portion 21 of lower socket 20. Force and sense pins are elastically supported by frame 11 of upper socket 10.

### FIELD OF THE INVENTION

The present invention relates to a Kelvin contact measurement device and a Kelvin contact measurement method. In the Kelvin contact measurement device, at least two contact pins are connected to one terminal of an object to be measured, and one of the two contact pins is connected to a forcing side for flowing a current and the other of the two contact pins is connected to a sensing side for detecting the current, thereby making electrical measurement of the object to be measured.

### BACKGROUND OF THE INVENTION

As a method of measuring a resistance value of an object to be measured without being influenced by circuit resistance of a measuring circuit and contact resistance between a contactor and a terminal in electrical measurement of the object to be measured, there is provided a Kelvin contact method. The object to be measured is a semiconductor device (such as a BGA, a CSP, or the like) or an electronic component that includes a plurality of terminals such as solder balls on a circuit surface thereof. In the Kelvin contact method, two contact pins are connected to one terminal, and a Kelvin contact achieved by connecting one of the contact pins to a forcing side of a tester that flows a current and connecting the other of the contact pins to a sensing side of the tester that detects the current is used. Then, when measuring the resistance value of the object to be measured, for example, a resistance value except a resistance value of the object to be measured is cancelled from a resistance value within the measuring circuit. Only the resistance value of the object to be measured can be thereby obtained.

As a conventional Kelvin contact testing device that uses the Kelvin contact method, there is provided a semiconductor wafer measuring needle that measures an electrical property of a chip in a wafer state, for example (refer to FIG. 7; refer to Patent Document 1). This needle includes a cylindrical first measuring needle portion 107, a second measuring needle portion 108 arranged on an inner side of the first measuring needle portion 107 through a spacing, an insulator 109 that achieves electrical insulation between the second measuring needle portion 108 and the first measuring needle portion 107, and an elastic member 110 that is arranged within the first measuring needle portion 107 and provides resilient force in a direction so that the second measuring needle portion 108 is protruded. Then, one of the first measuring needle portion 107 and the second measuring needle portion 108 is used for input, and the other of the first measuring needle portion 107 and the second measuring needle portion 108 is used for detection.

There is also provided a Kelvin spiral contactor 201, which is a Kelvin contact-type contactor that establishes electrical connection with a semiconductor device or an electronic component having spherical connection terminals and makes high-precision measurement. This connector includes on an insulating substrate two spiral contactors 202 and 203 each having a spiral shape when plan viewed. The two spiral contactors 202 and 203 are in contact with the spherical connection terminals, respectively. The spiral contactor 202 is formed of one contactor with a leading end thereof being free, and is formed to have the spiral shape so that a width of the spiral contactor 202 decreases gradually from a root thereof to the leading end thereof. Another spiral contactor 203 extends from the other opposing side. The spiral contactor 203 is formed to have the spiral shape so that a width of the spiral contactor 203 decreases gradually from a root thereof to a leading end thereof without interfering with spiral spacing of the spiral contactor 202. (Refer to FIGS. 8A and 8B, and Patent Document 2.)
[Patent Document 1]
   Japanese Utility Model Kokai Publication No. JP-U-63-14169
[Patent Document 2]
   Japanese Patent Kokai Publication No. JP-P2004-271290A

### SUMMARY OF THE DISCLOSURE

In the following, analyses on the related art are given by the present invention. The disclosures of the above mentioned Patent Documents are herein incorporated by reference thereto.

In the semiconductor wafer measuring needle described in Patent Document 1, however, the second measuring needle portion 108 disposed on the inner side of the cylindrical first measuring needle portion 107 is pressed by the elastic member 110, so as to enhance contact with a semiconductor wafer. However, the cylindrical first measuring needle portion 107 is not pressed. Thus, it may not be said that the contact between the first measuring needle portion 107 and the semiconductor wafer will always be improved.

In the Kelvin spiral contactor 201 described in Patent Document 2, contact between each of the two spiral contactors 202 and 203 and the spherical connection terminal is improved. However, when a positional deviation of the semiconductor device or the electronic component, or a positional deviation of the spherical connection terminal is present, the two spiral contactors may contact with each other, and highly precise measurement may not be able to be made, depending on the position at which the spherical connection terminal contacts with the two spiral contactors 202 and 203, respectively.

It is an object of the present invention to provide a stable Kelvin contact, even if a positional deviation of an object to be measured or a terminal is present.

According to a first aspect of the present invention, there is provided a Kelvin contact measurement device comprising at lease one force pin and at least one sense pin into contact with a ball terminal (per ball terminal) of an object to be measured, thereby measuring an electric property of the object to be measured.

Each of the at least one force pin and the at least one sense pin is formed to be extendable and contractable independently from one another so as to be urged against the ball terminal by an elastic member; the total number of the force pin(s) and the sense pin(s) provided per one ball terminal is at least three; and

at least one of the force pin(s) and at least one of the sense pin(s) are arranged to come into contact with the ball terminal, respectively, per one ball terminal.

In the Kelvin contact measurement device of the present invention, at least two of one of the force pin(s) and the sense pin(s) may be arranged, per one ball terminal, to allow contact with the ball terminal; and at least one of the other of the force pin(s) and the sense pin(s) may be arranged, per one ball terminal, to allow contact with the each ball terminal.

In the Kelvin contact measurement device of the present invention, the at least two of the force pins may be provided per one of the ball terminal; the at least two of the sense pins may be provided per one of the ball terminal; and respective centers of the force pins and respective centers of the sense pins per one of the ball terminal may be arranged to form a polygon.

In the Kelvin contact measurement device of the present invention,

a center of the at least two of the force pins for the ball terminal may be arranged on a diagonal line of the polygon; and a center of the at least two of the sense pins for the ball terminal may be arranged on a diagonal line of the polygon.

Preferably, the Kelvin contact measurement device of the present invention may include: a first socket including a concave portion for positioning the object to be measured so that the object to be measured can be received in and taken out of the concave portion; and a second socket including a frame that elastically supports each of the force pin(s) and each of the sense pin(s), the second socket being formed capable of being opened or closed relative to the first socket by an opening and closing mechanism.

Preferably, in the Kelvin contact measurement device of the present invention, the first socket includes a guide portion that limits shift of the object to be measured in a vertical direction or a horizontal direction.

According to a second aspect of the present invention, there is provided a Kelvin contact measurement method, which brings at least one force pin and at least one sense pin into contact with a ball terminal of an object to be measured, thereby measuring electric property of the object to be measured.

The force pin is constituted from a plurality of force pins or the sense pin is constituted from a plurality of sense pins. At least two of one of the force pins and the sense pins are arranged, per one ball terminal, to allow contact with the each ball terminal, and at least one of the other of the force pins and the sense pins is arranged, per one ball terminal, to allow contact with the each ball terminal, thereby measuring the electric property.

In the Kelvin contact measurement method of the present invention, at least two of sense pins and at least one of the force pin may be arranged per one ball terminal, thereby measuring the electric property.

In the Kelvin contact measurement method of the present invention, a plurality of the force pins and a plurality of the sense pins may be arranged per one ball terminal, and respective centers of the plurality of the force pins and respective centers of the plurality of the sense pins may be arranged per each ball terminal to form a polygon, thereby measuring the electric property.

In the Kelvin contact measurement method of the present invention, a center of the plurality of the force pins per each ball terminal may be arranged on a diagonal line of the polygon, a center of the plurality of sense pins per one ball terminal may be arranged on a diagonal line of the polygon, and at least one of the plurality of force pins and at least one of the plurality of sense pins may be brought, per each ball terminal, into contact with each ball terminal, respectively, thereby measuring the electric property.

In the Kelvin contact measurement method of the present invention, when the force pins and the sense pins are brought into contact with each ball terminal, it is preferable that each of the force pin(s) and each of the sense pin(s) are independently pressed against each ball terminal associated with the force pins and the sense pins, thereby measuring the electric property.

The meritorious effects of the present invention are summarized as follows.

According to the present invention (as set forth in aspects 1 through 2), even if a position of the object to be measured or the terminal is deviated, Kelvin contact can be made with stability.

### BRIEF DESCRIPTION OF THE DRAWINGS

FIG. 1 is a first schematic diagram showing a configuration of a Kelvin contact measurement device according to a first example of the present invention;

FIG. 2 is a second schematic diagram showing a configuration of the Kelvin contact measurement device according to the first example of the present invention;

FIG. 3 is a partially enlarged sectional view schematically showing a configuration of an upper socket of the Kelvin contact measurement device according to the first example of the present invention;

FIG. 4A is a plan view schematically showing a contact pattern (of a four-point contact) between an object to be measured and respective force and sense pins in the Kelvin contact measurement device according to the first example of the present invention, as seen from an X-X′ direction;

FIG. 4B is a sectional view schematically showing the contact pattern (of the four-point contact) between the object to be measured and the respective force and sense pins in the Kelvin contact measurement device according to the first example of the present invention, taken along a line Y-Y′;

FIG. 5A is a plan view schematically showing a contact pattern (of a three-point contact) between the object to be measured and the respective force and sense pins in the Kelvin contact measurement device according to the first example of the present invention, as seen from the X-X′ direction;

FIG. 5B is a sectional view schematically showing the contact pattern (of the three-point contact) between the object to be measured and the respective force and sense pins in the Kelvin contact measurement device according to the first example of the present invention, taken along the line Y-Y′;

FIG. 6A is a plan view schematically showing a contact pattern (of a two-point contact) between the object to be measured and the respective force and sense pins in the Kelvin contact measurement device according to the first example of the present invention, as seen from the X-X′ direction;

FIG. 6B is a sectional view schematically showing the contact pattern (of the two-point contact) between the object to be measured and the respective force and sense pins in the Kelvin contact measurement device according to the first example of the present invention, taken along the line Y-Y′;

FIG. 7 is a sectional view schematically showing a configuration of a Kelvin contact measurement device (a semiconductor wafer measuring needle) according to a first conventional art; and

FIGS. 8A and 8B are sectional views schematically showing a configuration of a Kelvin contact measurement device (a Kelvin spiral contactor) according to a second conventional art.

### PREFERRED MODES OF THE INVENTION

### FIRST EXAMPLE

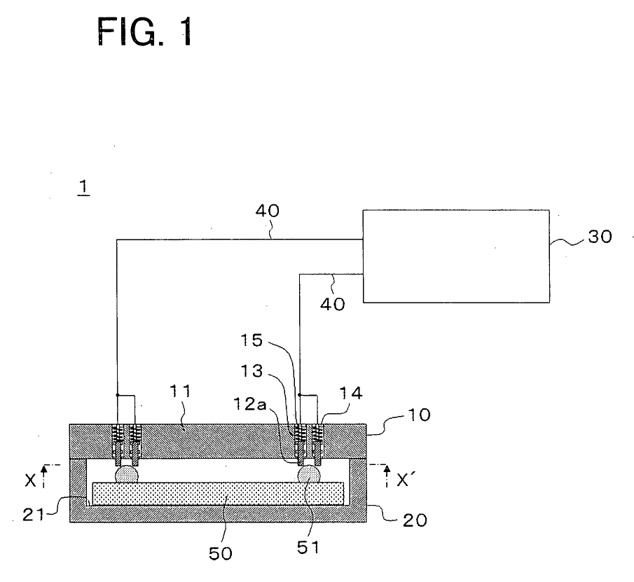

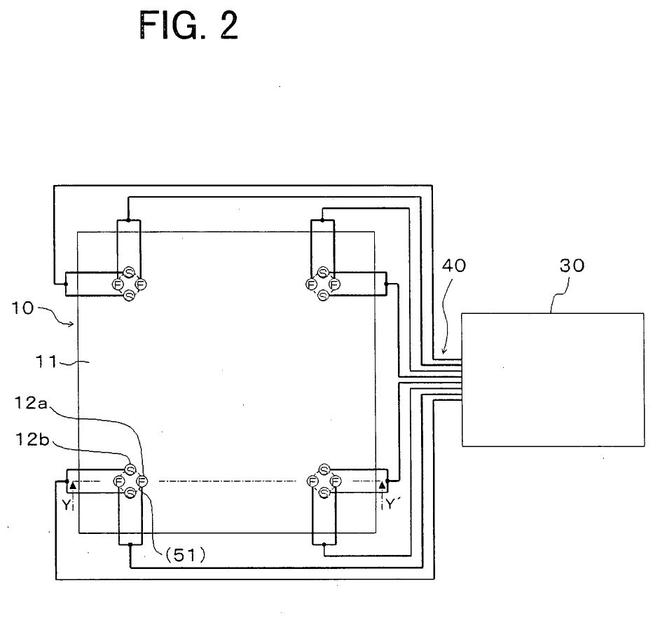

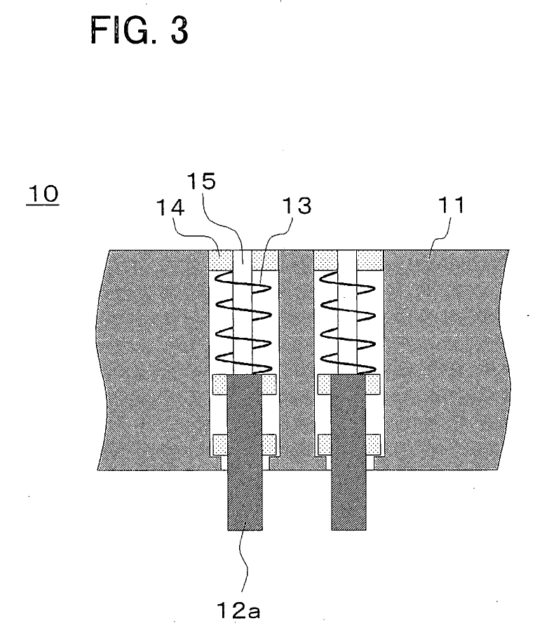

A Kelvin contact measurement device according to a first example of the present invention will be described. FIGS. 1 and 2 are schematic diagrams showing a configuration of the Kelvin contact measurement device according to the first example of the present invention. FIG. 3 is a partially enlarged sectional view schematically showing a configuration of an upper socket of the Kelvin contact measurement device according to the first example of the present invention. The upper socket and a lower socket in FIG. 1 correspond to those in a section taken along a line Y-Y′ in FIG. 2. The upper socket in FIG. 2 corresponds to the one in a plane as seen from a line X-X′ of FIG. 1.

A Kelvin contact measurement device 1 is a device in which two types of contact pins (constituted from force pins 12a and sense pins 12b) are connected to each terminal 51 of an object to be measured 50, the force pins 12a are electrically connected to a power supply device (not shown) in a tester 30, and the sense pins 12b are electrically connected to a measurement device (not shown) in the tester 30. The Kelvin contact measurement device 1 mainly includes an upper socket 10, a lower socket 20, a tester 30, and lines 40.

The upper socket 10 is a lid-like socket for bringing the terminal 51 of the object to be measured 50 placed in a concave portion 21 of the lower socket 20 into contact with each of the force pins 12a and the sense pins 12b. The upper socket 10 can be open or closed with respect to the lower socket 20 by an opening and closing mechanism not shown. The upper socket 10 can be moved relative to the lower socket 20 within a predetermined range using the opening and closing mechanism, and is arranged in a given position relative to the lower socket 20 when a concave portion 21 of the lower socket 20 is closed. The upper socket 10 includes a frame (or plate) 11, force pins 12a, sense pins 12b, elastic members (springs) 13, supporting members 14, and conducting wires 15.

The frame 11 is a member that expendably and contractably supports each of the two force pins 12a and each of the two sense pins 12b for each terminal 51 in positions corresponding to each terminal 51 of the object to be measured 50. The frame 11 is electrically insulated from each force pin 12a and each sense pin 12b. In the frame 11, holes for inserting the force pins 12a or the sense pins 12b are formed in positions corresponding to each terminal 51 of the object to be measured 50. Four holes are formed per each terminal 51. Preferably, a shape formed when respective centers of the holes are connected is a rhombus (or preferably, square), and diagonal lines of the shape formed of the four holes are generally parallel (or generally perpendicular) to sidewall surfaces of the concave portion 21 of the lower socket 20. The force pin 12a or the sense pin 12b, an elastic member 13, and a supporting member 14 are arranged in each of the holes.

The force pin 12a is a contact pin that is extendable and contractable for coming into contact with the corresponding terminal 51 of the object to be measured 50, and is electrically connected to the power supply device (not shown) in the tester 30 through a conducting wire 15 and a line 40. The sense pin 12b is a contact pin that is extendable (expandable) and contractable (retractable) for coming into contact with the corresponding terminal 51 of the object to be measured 50, and is electrically connected to the measurement device (not shown) in the tester through a conducting wire 15 and a line 40. The force pin 12a and the sense pin 12b are each formed to be extendable and contractable independently from one another. It is preferred that for each terminal 51, two force pins 12a are provided, and that two force pins 12a are arranged in opposing two of a set of four holes (in the frame 11) on a first diagonal line. It is preferred that for each terminal 51, two sense pins 12b are provided, and that two sense pins 12b are arranged in opposing two of the set of the four holes (in the frame 11) on a second diagonal line.

Referring to FIG. 3, the elastic member 13 urges (i.e., exerting a biasing force against) the force pin 12a or the sense pin 12b toward the object to be measured 50. The elastic member 13 is arranged in each hole in the frame 11. One end of the elastic member 13 is in contact with the supporting member 14, while the other end of the elastic member 13 is in contact with the force pin 12a or the sense pin 12b. Insulating members (rings) 16 are interposed between the inner wall of the hole and the force pin 12a or the sense pin 12b. The insulating members also sense as sliding aids and separators for retaining the angular position of the force pin (or sense pin) in a desired attitude (upright) with respect to the frame 11.

The supporting member 14 is a member for supporting one end of the elastic member 13 in each hole in the frame 11 and is fixed to the frame 11. The supporting member 14 is electrically insulated from each of the force pin 12a and the sense pin 12b. The conducting wire (or rod or pin) 15 is a conducting wire for electrically connecting the force pin 12a or the sense pin 12b to the line 40, and passes through the supporting member 14.

Now, turning again to FIG. 1, in the lower socket 20, the concave portion 21 is formed. The concave portion 21 positions the object to be measured 50 so that the object to be measured 50 can be taken in or out of the concave portion 21. The concave portion 21 is formed to be rectangular as seen from a direction of a normal line with respect to a base surface of the concave portion 21. The concave portion 21 is formed to be larger than a outer contour of the object to be measured 50 so that the object to be measured 50 can be taken in and out of the concave portion 21. The sidewall surfaces of the concave portion 21 are formed to be generally parallel to end portions of the object to be measured 50.

The tester 30 is a tester conforming to a Kelvin contact method capable of measuring a resistance value of the object to be measured 50 without being influenced by circuit resistance of a measuring circuit and contact resistance between the terminal 51 and each of the contact pin 12a and 12b. The tester 30 includes a power supply device (not shown) for supplying a current and the measurement device (not shown) that measures the current. The power supply device (not shown) is electrically connected to each force pin 12a through the line 40 and the conducting wire 15, and can be switched for each terminal 51 of the object to be measured 50. The measurement device (not shown) is electrically connected to each force pin 12b through the line 40 and the conducting wire 15, and can be switched for each terminal 51 of the object to be measured 50.

When a four-terminal method is used, for example, the tester 30 is switched to a connection state connecting with the force pins 12a and the sense pins 12b corresponding to the two terminals 51 for the object to be measured 50. One or two force pins 12a corresponding to a first one of the terminals 51 and one or two force pins 12a corresponding to a second one of the terminals 51 apply a current to the object to be measured 50, while one or two sense pins 12b corresponding to the first one of the terminals 51 and one or two sense pins 12b corresponding to the second one of the terminals 51 measure a potential across the two terminals 51. To be more specific, the tester 30 supplies the current from the power supply device (not shown) to the object to be measured 50 through the lines 40, conducting wires 15, force pins 12a, and terminals 51. Then, the potential is input to the measurement device (not shown) from the object to be measured 50 through the terminals 51, sense pins 12b, conducting wires 15, and lines 40. An electric property is thereby detected.

The lines 40 are lines for electrically connecting each force pin 12a and each sense pin 12b to the tester 30. Each of the lines 40 is branched (bifurcated) midway and connected to the two force pins 12a or the two sense pins 12b corresponding to one terminal 51.

The object to be measured 50 is a semiconductor device or an electronic component including a plurality of terminals 51 provided on electrodes (not shown), respectively, on a circuit surface. The contour of the object to be measured 50 is rectangular, for example. The terminal 51 is a ball terminal with a surface thereof being, e.g., spherical. A solder ball, for example, can be employed as the terminal 51.

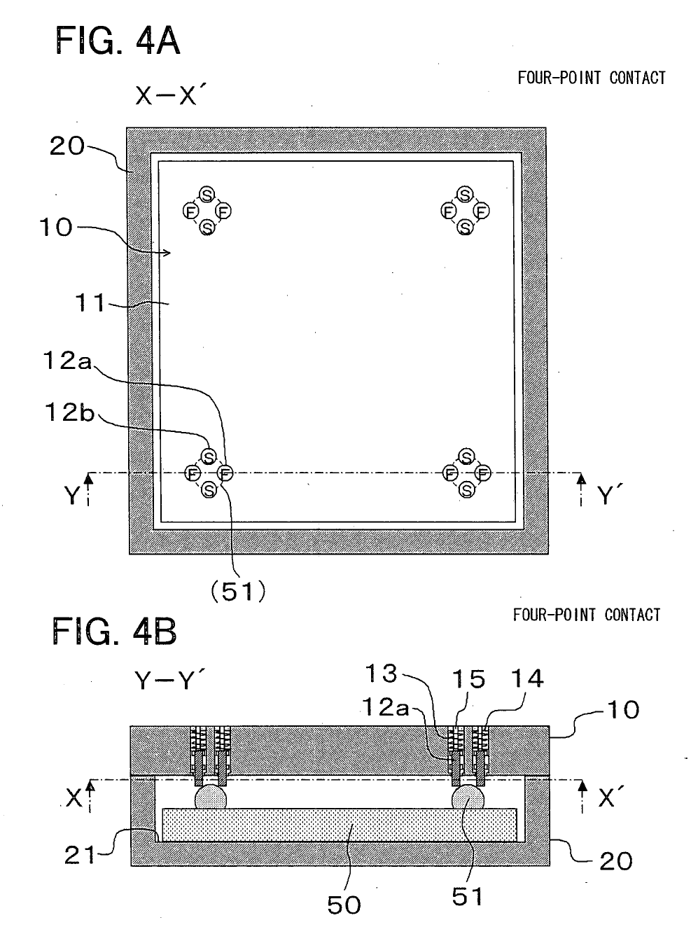

Next, a contact pattern between an object to be measured and the respective force and sense pins in the Kelvin contact measurement device according to the first example of the present invention will be described using drawings. FIGS. 4A to 6B are plan views “A” as seen from an X-X′ direction, respectively, and sectional views “B” taken along a line Y-Y′, respectively. Each of FIGS. 4A to 6B schematically shows the contact pattern between the object to be measured and the respective force and sense pins in the Kelvin contact measurement device according to the first example of the present invention.

Referring to FIGS. 4A and 4B, when the object to be measured 50 is placed in a (optimal) middle (or in the vicinity thereof) of the concave portion 21 of the lower socket 20 and the upper socket 10 is placed over the lower socket 20 for closing, each terminal 51 of the object to be measured 50 comes into contact with the corresponding two force pins 12a and the corresponding two sense pins 12b. That is, the four contact pins 12a and 12b make contact with one terminal 51.

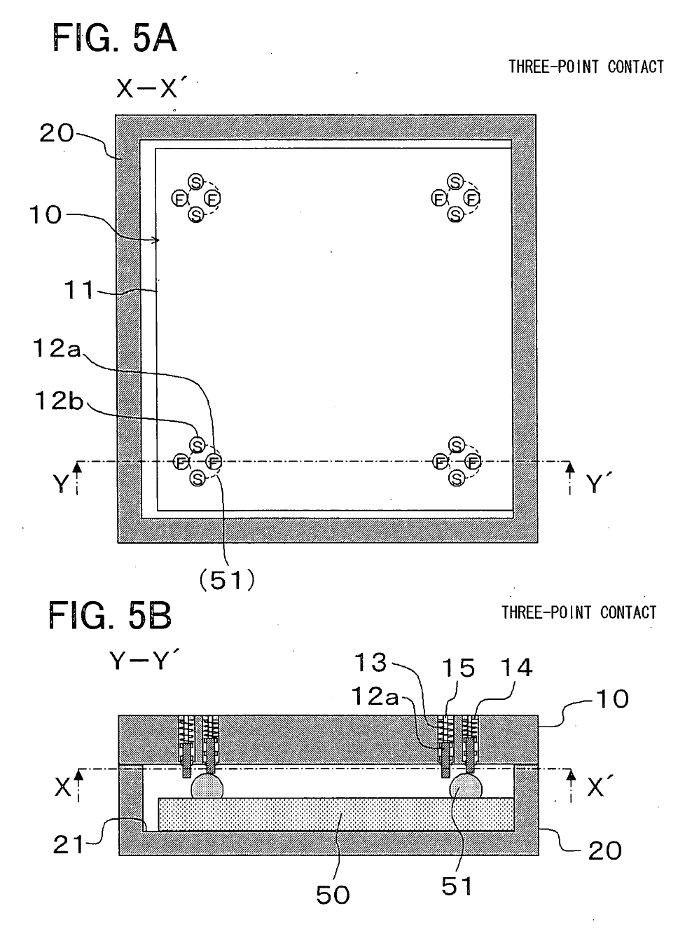

Referring to FIGS. 5A and 5B, assume that the object to be measured 50 is not in contact with corner portions of the concave portion 21 of the lower socket 20 and is placed in a position in contact with (or in the vicinity of) a sidewall surface of the concave portion 21, and then the upper socket 10 is placed over the lower socket 20, for closing. Then, when the object to be measured 50 is in contact with a right (or left) sidewall surface as shown in FIG. 5A, each terminal 51 of the object to be measured 50 comes into contact with corresponding one force pin 12a (right hand ones) and the corresponding two sense pins 12b. That is, even if a position of the object to be measured 50 is deviated to a position in contact with (or in the vicinity of) the sidewall surface of the concave portion 21 within the concave portion 21 of the lower socket 20, three contact pins 12a and 12b come into contact with one terminal 51. In this case, the remaining one contact pin (12a or 12b) is not in contact with the one terminal 51. Incidentally, each terminal 51 of the object to be measured 50 will come into contact with the corresponding two force pins 12a and the corresponding one sense pin 12b when the object to be measured 50 is in contact with an upper or lower sidewall surface in FIG. 5A.

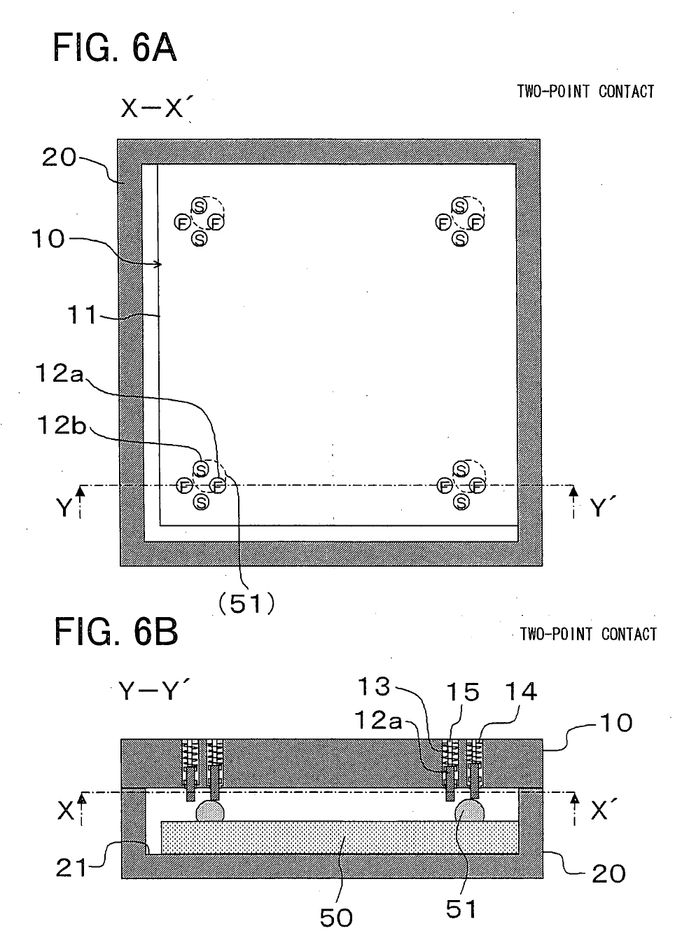

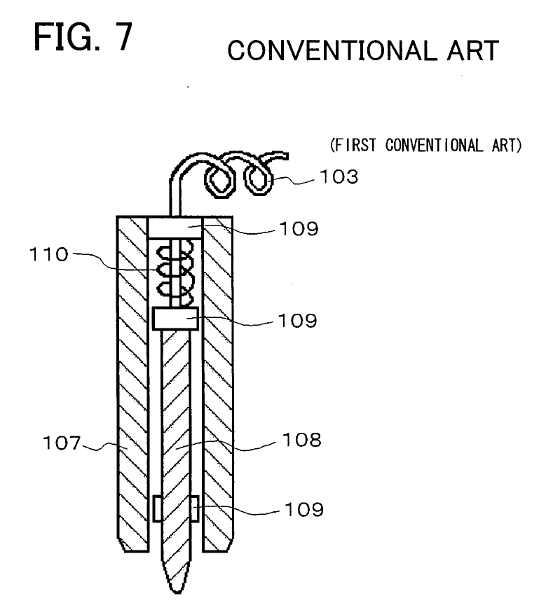

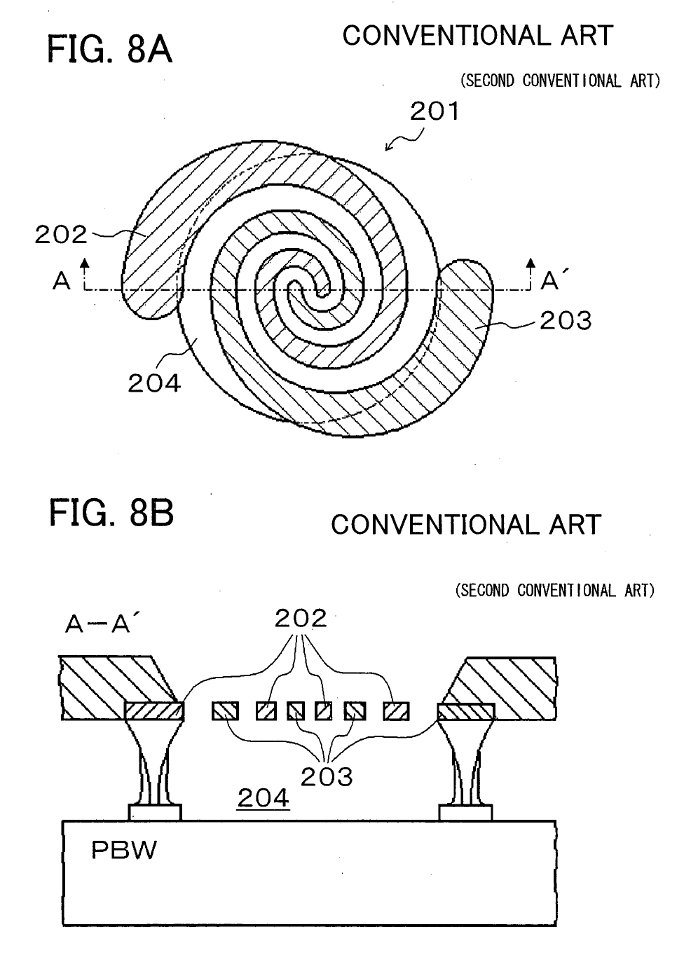

Referring to FIGS. 6A and 6B, assume that the object to be measured 50 is placed in a position in contact with (or in the vicinity of) a corner portion of the concave portion 21 of the lower socket 20 and the upper socket 10 is placed over the lower socket 20, for closing. Then, each terminal 51 of the object to be measured 50 comes into contact with corresponding one force pin 12a and corresponding one sense pin 12b. That is, even if the position of the object to be measured 50 is deviated (from the optimal middle position) to a position in contact with (or in the vicinity of) the corner portion of the concave portion 21 within the concave portion 21 of the lower socket 20, the two contact pins 12a and 12b come into contact with one terminal 51. In this case, the remaining two contact pins 12a and 12b are not in contact with the one terminal 51.

According to the first example, even if the position of the object to be measured 50 is deviated within the concave portion 21 in the lower socket 20, and the position of each terminal 51 is deviated, one of the two force pins 12a and one of the two sense pins 12b for one terminal 51 can come into contact with the one terminal 51 without fail. This ensures achievement of a Kelvin contact.

In the first example, the four contact pins 12a and 12b are provided for one terminal 51. Even if the position of the object to be measured 50 is deviated in the concave portion 21 of the lower socket 20, three, five, or more contact pins may be arranged for one terminal 51, as an alternative example, provided that at least two contact pins (constituted from one force pin 12a and one sense pin 12b) can be always brought into contact with the one terminal 51. When two or more force pins and two or more sense pins are provided for one terminal 51, it is preferred that respective centers of the force pins 12a and respective centers of the sense pins 12b are arranged to form a polygon. It is preferred that, for the one terminal 51, the center between the opposing force pins 12a is arranged on a diagonal line of the polygon, and the center between the opposing sense pins 12b is arranged on a diagonal line of the polygon.

In the first example, in the lower socket 20, the position of the object to be measured 50 may be deviated within the concave portion 21 in two directions of vertical and horizontal directions (see, e.g., FIG. 6A). A guide portion may be provided so that a shift (a positional deviation) of the object to be measured 50 in one of the vertical and horizontal directions is limited.

It should be noted that other objects, features and aspects of the present invention will become apparent in the entire disclosure and that modifications may be done without departing the gist and scope of the present invention as disclosed herein and claimed as appended herewith.

Also it should be noted that any combination of the disclosed and/or claimed elements, matters and/or items may fall under the modifications aforementioned.

What is claimed is:

1. A Kelvin contact measurement device comprising:
at least one force pin and at least one sense pin adapted to come into contact with a ball terminal of an object to be measured for measuring electric property of said object to be measured; wherein
each of said at least one force pin and said at least one sense pin is formed to be extendable and contactable independently from one another so as to be urged against said ball terminal by an elastic member;
a total number of said at least one force pin and said at least one sense pin provided per one ball terminal is at least three; and
at least one of said force pin(s) and at least one of said sense pin(s) are arranged to come into contact with said ball terminal, respectively, per one of said ball terminal.

2. The Kelvin contact measurement device according to claim 1, wherein
at least one of said force pin and at least two of said sense pins are arranged, per one ball terminal, to allow contact with said ball terminal.

3. The Kelvin contact measurement device according to claim 1, wherein
at least two of said force pins are provided per one of said ball terminal;
at least two of said sense pins are provided per one of said ball terminal; and
respective centers of said force pins and respective centers of said sense pins for said ball terminal are arranged to form a polygon.

4. The Kelvin contact measurement device according to claim 3, wherein
a center of said at least two of said force pins for said ball terminal are arranged on a diagonal line of said polygon; and
a center of said at least two of said sense pins for said ball terminal are arranged on a diagonal line of said polygon.

5. The Kelvin contact measurement device according to claim 1, comprising:
a first socket including a concave portion for positioning said object to be measured so that said object to be measured can be received in and taken out of said concave portion; and
a second socket including a frame that elastically supports each of said force pin(s) and each of said sense pin(s), said second socket being formed capable of being opened or closed relative to said first socket by an opening and closing mechanism.

6. The Kelvin contact measurement device according to claim 5, wherein said first socket includes a guide portion that limits shift of said object to be measured in a vertical direction or a horizontal direction.

7. A Kelvin contact measurement method comprising:
bringing at least one force pin and at least one sense pin into contact with a ball terminal of an object to be measured, wherein
at least one force pin and at least one sense pin are arranged per one ball terminal to allow contact with said ball terminal, and at least one of another pin selected from the group of said at least one force pin and said at least one sense pin is arranged per said one ball terminal to allow contact with said ball terminal; and measuring electric property of said object to be measured.

8. The Kelvin contact measurement method according to claim 7, wherein at least two of said sense pins and said at least one force pin are arranged per one ball terminal, thereby measuring the electric property.

9. The Kelvin contact measurement method according to claim 7, wherein a plurality of said force pins and a plurality of said sense pins are arranged per one ball terminal, and respective centers of said plurality of force pins and respective centers of said plurality of sense pins are arranged per each ball terminal to form a polygon, thereby measuring the electric property.

10. The Kelvin contact measurement method according to claim 9, wherein a center of said plurality of force pins per said ball terminal is arranged on a diagonal line of said polygon, a center of said plurality of sense pins per said ball terminal is arranged on a diagonal line of said polygon, and at least one of said plurality of force pins and at least one of said plurality of sense pins are brought, per said ball terminal, into contact with said ball terminal, respectively, thereby measuring the electric property.

11. The Kelvin contact measurement method according to claim 7, wherein when the force pin(s) and the sense pin(s) are brought into contact with each of said ball terminal, each of the force pin(s) and each of the sense pin(s) are independently pressed against each of said ball terminal associated with said force pin(s) and said sense pin(s), thereby measuring the electric property.
